(19) United States
(12) Patent Application Publication
(10) Pub. No.: US 2025/0308861 A1
(43) Pub. Date: Oct. 2, 2025

(54) PLASMA PROCESSING APPARATUS

(71) Applicants: Beijing E-Town Semiconductor Technology Co., Ltd., Beijing (CN); Mattson Technology, Inc., Fremont, CA (US)

(72) Inventors: Jianpin Zheng, Singapore (SG); Saikumar Kodumuri, Singapore (SG); Adrian Tan, Singapore (SG); Subrahmanyam Venkata Rama Kommisetti, Singapore (SG); Michael Vanabbema, Singapore (SG); Ludovic Goffart, Singapore (SG); Sim Darius, Singapore (SG)

(21) Appl. No.: 19/088,074

(22) Filed: Mar. 24, 2025

Related U.S. Application Data
(60) Provisional application No. 63/571,168, filed on Mar. 28, 2024.

(51) Int. Cl. H01J 37/32

(52) U.S. Cl. CPC H01J 37/32651; H01J 37/3244; H01J 37/32541; H01J 37/32596; H01J 2237/3346

(57) ABSTRACT

A plasma processing apparatus is disclosed. The apparatus includes a processing chamber; a workpiece support disposed in the processing chamber configured to support a workpiece during processing; a hollow cathode disposed in the processing chamber configured to produce a plasma in the processing chamber; a gas distribution system configured to provide process gas to the processing chamber; and a shield disposed in the processing chamber. The hollow cathode is disposed adjacent to a perimeter of the workpiece support and the workpiece. The shield is configured to be adjusted with respect to an X-Y plane. Systems and methods for processing workpieces are also disclosed.

### CROSS-REFERENCE TO PRIORITY APPLICATIONS

This application claims the benefit of priority to U.S. Provisional Application No. 63/571,168 filed Mar. 28, 2024, the entirety of which is incorporated by reference herein.

### FIELD

The present disclosure relates generally to a plasma processing apparatus for plasma processing of a workpiece. More specifically, the present disclosure is directed to a plasma processing system including a hollow cathode.

### BACKGROUND

RF plasmas are used in the manufacture of devices such as integrated circuits, micromechanical devices, flat panel displays, and other devices. RF plasma sources used in modern plasma etch applications are required to provide a high plasma uniformity and a plurality of plasma controls, including independent plasma profile, plasma density, and ion energy controls. RF plasma sources typically must be able to sustain a stable plasma in a variety of process gases and under a variety of different conditions (e.g., gas flow, gas pressure, etc.). In addition, it is desirable that RF plasma sources produce a minimum impact on the environment by operating with reduced energy demands and reduced EM emission.

Problems with plasma processing can include processing uniformity and difficulty processing only certain portions of a workpiece while not processing or damaging other portions of the workpiece. For instance, for certain applications it may be desirable to etch or remove materials from certain areas of the workpiece (e.g., the perimeter) while not damaging or removing any other materials from other areas of the workpiece. Accordingly, improved plasma processing apparatuses and systems are needed.

### SUMMARY

Aspects and advantages of embodiments of the present disclosure will be set forth in part in the following description, or may be learned from the description, or may be learned through practice of the embodiments.

Aspects of the present disclosure are directed to a plasma processing apparatus. The plasma processing apparatus includes a processing chamber, a workpiece support disposed in the in the processing chamber configured to support a workpiece during processing, and a hollow cathode disposed in the processing chamber. The hollow cathode is configured to produce a plasma in the processing chamber. The hollow cathode is disposed adjacent to a perimeter of the workpiece support and the workpiece. The plasma processing apparatus includes a gas distribution system configured to provide process gas to the processing chamber and a shield disposed in the processing chamber. The shield is configured to be adjusted with respect to an X-Y plane.

Aspects of the present disclosure are also directed to a processing system for processing a plurality of workpieces. The system includes a processing module including a first processing chamber and a second processing chamber. A first workpiece support is disposed in the first processing chamber and is configured to support a first workpiece during processing. A second workpiece support is disposed in the second processing chamber and is configured to support a second workpiece during processing. A first hollow cathode is disposed in the first processing chamber and is configured to produce a plasma in the first processing chamber. The first hollow cathode is disposed adjacent to a perimeter of the first workpiece support and a first workpiece. A second hollow cathode is disposed in the second processing chamber and is configured to produce a second plasma in the second processing chamber. The second hollow cathode is disposed adjacent to a perimeter of the second workpiece support and the second workpiece. The system includes a first top including a first shield having a first workpiece facing surface. The first shield is configured to be adjusted with respect to an X-Y plane. The system includes a second top including a second shield having a second workpiece facing surface. The second shield is configured to be adjusted with respect to an X-Y plane. The system also includes a gas distribution system configured to provide process gas to the first processing chamber and the second processing chamber.

Aspects of the present disclosure are also directed to a method for processing a workpiece in a plasma processing apparatus. The method includes centering a shield disposed in a processing chamber; transferring a workpiece to a workpiece support disposed in a processing chamber; moving the shield to a processing position in the processing chamber; performing a treatment process on a peripheral portion of the workpiece with plasma generated from a hollow cathode disposed in the processing chamber, the hollow cathode disposed adjacent to a perimeter of the workpiece support; and optionally, removing the workpiece from the processing chamber.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional schematic view of an example plasma processing apparatus according to example embodiments of the present disclosure;

FIG. 2 depicts a cross-sectional schematic view of an example plasma processing apparatus according to example embodiments of the present disclosure;

FIG. 3 depicts an example top down view of a gas showerhead for a plasma processing apparatus according to example embodiments of the present disclosure;

FIG. 4 depicts a perspective view of an example hollow cathode for a plasma processing apparatus according to example embodiments of the present disclosure;

FIG. 5 depicts a cross-sectional schematic view of an example hollow cathode for a plasma processing apparatus according to example embodiments of the present disclosure;

FIG. 6 depicts a cross-sectional schematic view of an example hollow cathode for a plasma processing apparatus according to example embodiments of the present disclosure;

FIG. 6a depicts a partial cross-sectional schematic view of an example portion of a hollow cathode for a plasma processing apparatus according to example embodiments of the present disclosure;

FIG. 7 depicts a cross-sectional schematic view of an example workpiece support according to example embodiments of the present disclosure;

FIG. 8 depicts a perspective view of portions of a showerhead according to example aspects of the present disclosure;

FIG. 9 depicts partial perspective cut-out view of portions of a showerhead according to example embodiments of the present disclosure;

FIG. 10 depicts a cross-sectional schematic view of an example plasma processing apparatus according to example embodiments of the present disclosure;

FIG. 11 depicts a cross-sectional schematic view of an example plasma processing apparatus according to example embodiments of the present disclosure;

FIG. 12 depicts a partial cross-sectional schematic view of an example showerhead and top insert according to example embodiments of the present disclosure;

FIG. 13 depicts a partial perspective view of a top insert according to example embodiments of the present disclosure;

FIG. 14 depicts a partial perspective view of a top insert according to example embodiments of the present disclosure;

FIG. 15 depicts a partial perspective view of a top insert according to example embodiments of the present disclosure;

FIG. 16 depicts a partial perspective view of an angular adjustment device according to example embodiments of the present disclosure;

FIG. 17 depicts a cross-sectional schematic view of an example plasma processing apparatus according to example embodiments of the present disclosure;

FIG. 18 depicts a partial top-down perspective view of an example plasma processing apparatus according to example embodiments of the present disclosure;

FIG. 19 depicts a partial cross sectional perspective view of an example plasma processing apparatus according to example embodiments of the present disclosure;

FIG. 20 depicts a partial perspective view of an example workpiece support according to examples embodiments of the present disclosure; and

FIG. 21 depicts a flow chart diagram of a method for processing a workpiece according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece. A “remote plasma” refers to a plasma generated remotely from a workpiece, such as in a plasma chamber separated from a workpiece by a separation grid. A “direct plasma” refers to a plasma that is directly exposed to a workpiece, such as a plasma generated in a processing chamber having a pedestal operable to support the workpiece. As used herein, a “peripheral portion” of a workpiece includes the portion of the workpiece within 15 mm of a perimeter edge of the workpiece.

As used herein, use of the term “about” in conjunction with a stated numerical value can include a range of values within 10% of the stated numerical value.

Conventional plasma processing apparatuses may include a processing chamber for treating one or more workpieces with plasma. Such chambers generally include a plasma generation source (e.g., an induction coil) disposed on or around at least a portion of the chamber. Often times, the walls of the processing chamber can be formed from a dielectric material (e.g., ceramic). During processing, material residue and/or material deformations can form around the periphery of the semiconductor wafer. Accordingly, there is a need to selectively remove materials from the peripheral portion of the wafer without exposing the center of the workpiece to additional processing conditions (e.g., plasma). Certain plasma chambers are capable of inducing plasma remotely or within the chamber utilizing a variety of coils that are typically disposed on or around areas of the chamber itself. However, generation of plasma in such a manner exposes the entire workpiece to the plasma.

According to examples of the present disclosure, a plasma processing apparatus is disclosed that includes a processing chamber, a workpiece support disposed in the processing chamber configured to support a workpiece during processing and a hollow cathode disposed in the processing chamber. The hollow cathode is configured to produce a plasma in the processing chamber. The hollow cathode is disposed adjacent to a perimeter of the workpiece support and the workpiece. A gas distribution system for supplying process gas to the processing chamber is also provided. The hollow cathode is configured to etch a peripheral portion of the workpiece during processing.

The plasma processing apparatus according to example embodiments of the present disclosure can provide numerous benefits and technical effects. For instance, plasma processing apparatus provides an efficient way to ignite and generate plasma, reducing overall operational costs. Further, the plasma processing apparatus provides a mechanism to expose only the peripheral portion of the workpiece to dense plasma species to etch only the peripheral portion of the workpiece.

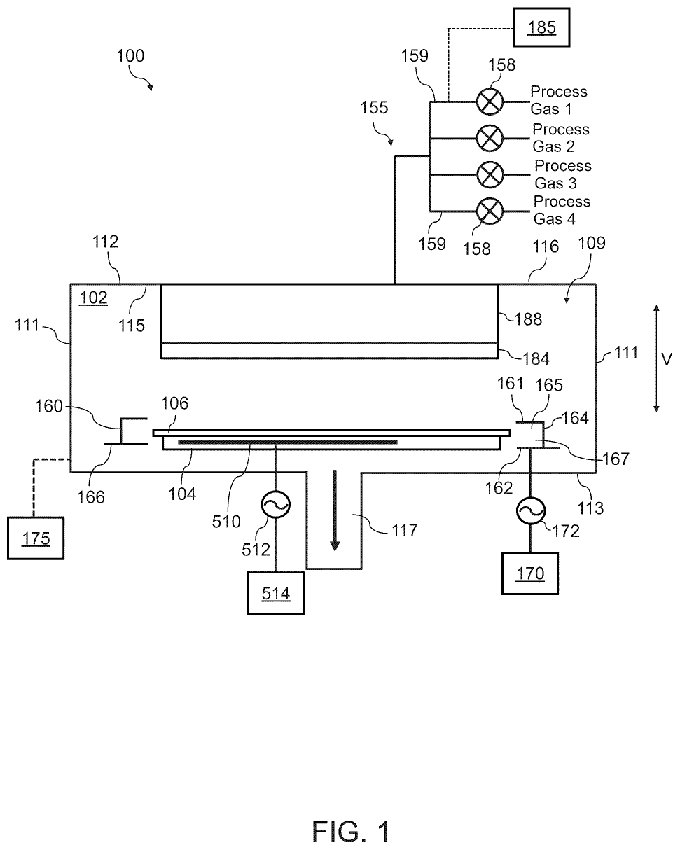

FIG. 1 depicts a plasma processing apparatus 100 according to an example embodiment of the present disclosure. The plasma processing apparatus 100 includes a processing chamber 109 defining an interior space 102. A workpiece support 104 (e.g., pedestal) is used to support a workpiece 106, such as a semiconductor wafer, within the interior space 102. Workpiece support 104 can include one or more support pins, such as at least three support pins, extending from workpiece support 104. (Not shown). In some embodiments, workpiece support 104 can be spaced from the top of the processing chamber 109. The processing chamber 109 includes one or more sidewalls 111, a top 112, and a bottom 113. The top 112 and/or bottom 113 can form a flat surface or can be curved or slightly domed. The top 112 has a first surface 115 facing the interior space 102 of the processing chamber 109 and a second surface 116 opposite from the first surface 115 that faces externally. The sidewalls 111, top 112, and/or bottom 113 of the processing chamber 109 can be formed from a metal material or a coated metal material. For instance, the sidewalls 111, top 112, and/or bottom 113 can be formed from a metal material that is coated with a dielectric material. For instance, the surfaces of the sidewalls 111, top 112, and/or bottom 113 facing the interior space 102 can be coated with a dielectric material.

An exhaust 117 can be located about the bottom 113 of the processing chamber 109 and can be connected to a pump in order to maintain a desired vacuum environment or other desired pressure condition in the processing chamber 109. In some embodiments, the exhaust is located in a central location under the workpiece 106 and workpiece support 104. One or more vacuum pumps can be configured to maintain a vacuum (e.g., VAT valve) in the processing chamber 109. Further, process gas flow in and out of the processing chamber 109 can be adjusted to achieve the desired vacuum pressure in the processing chamber 109. In embodiments, the vacuum pressure is from about 0.01 Torr to about 10 Torr, such as from about 0.5 Torr to about 9 Torr, such as from about 1 Torr to about 8 Torr, such as from about 2 Torr to about 6 Torr. In some embodiments, the vacuum pressure is from about 0.05 Torr to about 1 Torr, from 0.3 Torr to about 0.8 Torr, from about 0.5 Torr to about 0.7 Torr. The exhaust 117 can also be utilized to evacuate process gas from the processing chamber 109. The vacuum pressure can be selected based on factors such as the desired process (e.g., etch or material deposition) and the workpiece materials.

As shown in FIG. 1, according to example aspects of the present disclosure, the apparatus 100 can include a gas delivery system 155 configured to deliver process gas to the processing chamber 109, for instance, via a gas distribution channel or other distribution system (e.g., showerhead 184). The gas delivery system 155 can include a plurality of feed gas lines 159. The feed gas lines 159 can be controlled using valves 158 and/or gas flow controllers 185 to deliver a desired amount of gases into the processing chamber 109 as process gas. The gas delivery system 155 can be used for the delivery of any suitable process gas. As used herein “process gas” refers to any suitable gas and includes vapors. Example process gases include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A control valve 158 (e.g., mass flow controller(s)) can be used to control a flow rate of each feed gas line to flow a process gas into the processing chamber 109. In embodiments, the gas delivery system 155 can be controlled with a gas flow controller 185.

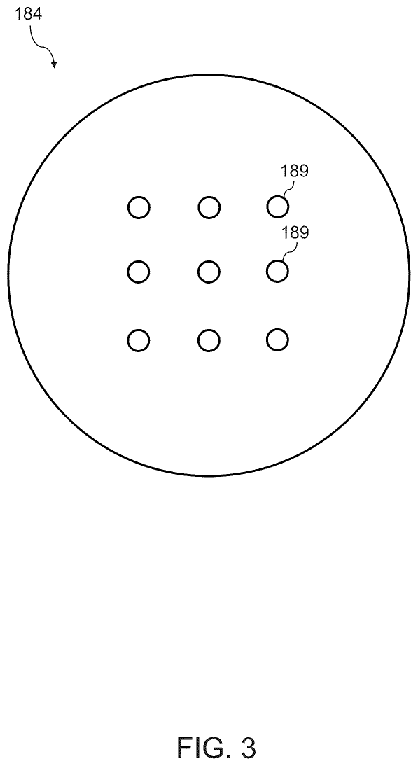

The gas delivery system 155 can be configured to deliver process gas at a high velocity to the processing chamber 109. For instance, the gas delivery system 155 can include a showerhead 184 as illustrated in FIG. 3. As shown, the showerhead 184 can include one or more (e.g., a plurality) apertures 189 disposed therein. Process gas can be supplied to and exit the showerhead 184 into the processing chamber 109 via the apertures 189. To achieve a high velocity flow of process gas into the processing chamber 109, the apertures 189 each can have a diameter ranging from about 0.3 mm to about 1.5 mm, such as about 0.7 mm. In such embodiments having apertures 189 with such small diameters can provide a supersonic spray of process gas into the processing chamber 109, such as by a process called choked flow. In such embodiments, diffusion of process gas in the upper portions of the processing chamber 109 is limited. Indeed, having a high velocity process gas flow also facilitates mixing of gas molecules and species in the plasma within the processing chamber 109. As such, process gas can be provided to the workpiece 106 surface maintained at a higher velocity. When the process gas contacts the top surface of the workpiece 106, it can then flow away from the center of the workpiece 106 and to the perimeter of the workpiece 106. Accordingly, the showerhead 184 as described can be useful for maintaining proper gas flow to the hollow cathode 160 to generate a dense plasma as will be further described hereinbelow. The showerhead 184 can be disposed along a bottom surface of a shield 188 that is also disposed within the processing chamber 109.

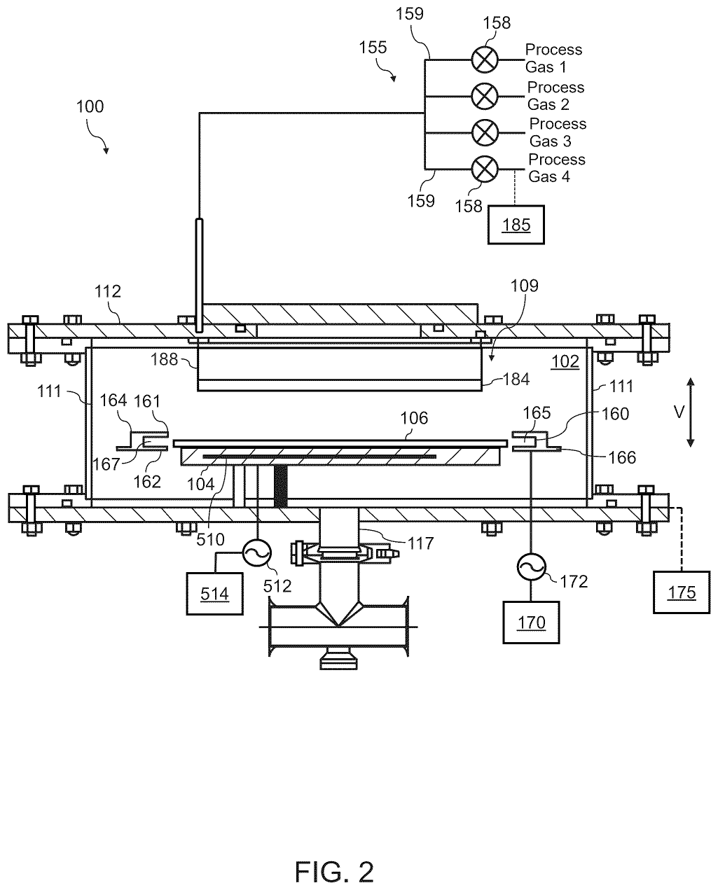

Referring back to FIGS. 1-2, the workpiece support 104 can include a bias source having a bias electrode 510 in the workpiece support 104. The bias electrode 510 can be coupled to an RF power generator 514 via a suitable matching network 512. When RF power is applied to the bias electrode 510, species generated in the plasma are attracted to the perimeter of the workpiece 106 and away from the plasma generation zone 167 in the hollow cathode 160. For instance, when negative voltage (e.g., DC bias) is applied to the bias electrode 510, ions from the plasma in the plasma generation zone 167 are attracted to the perimeter of the workpiece 106. Thus, ion acceleration can be achieved via the bias source in the workpiece support 104.

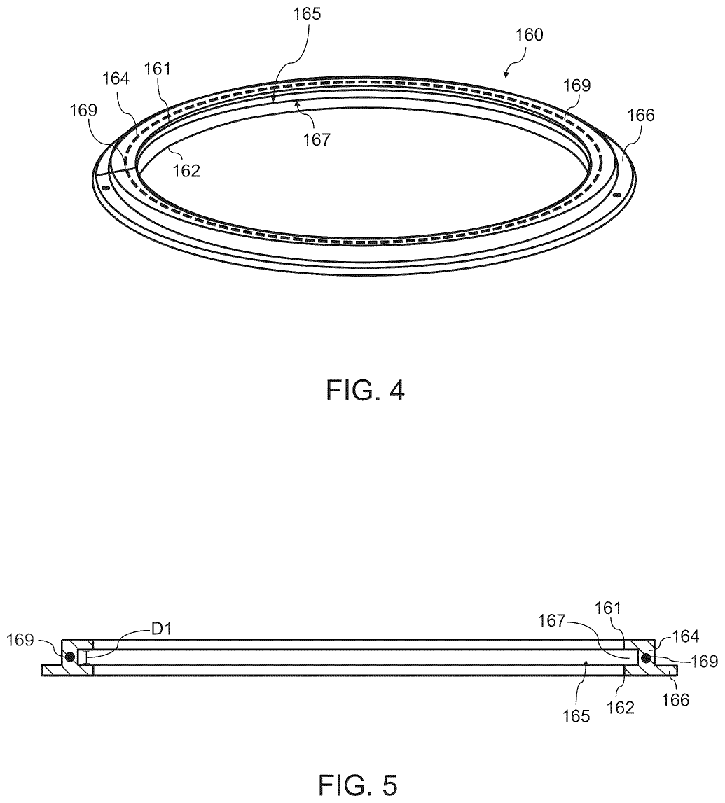

The apparatus 100 further includes a hollow cathode 160 disposed within the processing chamber 109. The hollow cathode 160 can be annular in nature and is disposed around the perimeter of the workpiece support 104 and the workpiece 106. The distance between the perimeter edge of the workpiece 106 and the hollow cathode 160 may be in a range from about 1 mm to about 10 mm, such as from about 2 mm to about 9 mm, such as from about 3 mm to about 8 mm, such as from about 4 mm to about 7 mm, such as from about 5 mm to about 6 mm. In certain embodiments, the distance between the perimeter edge of the workpiece 106 and the hollow cathode 160 is from about 1 mm to about 5 mm. For instance, in certain embodiments, the distance between the perimeter edge of the workpiece 106 and the hollow cathode 160 is more than 5 mm so as not to negatively affect the stability of the plasma generated in the hollow cathode 160. The hollow cathode can be formed from metal materials, such as aluminum. In embodiments, the hollow cathode 160 is a C-shaped hollow cathode. As shown in FIGS. 4-5, the hollow cathode 160 can have a first end 161 and a second end 162 connected via a C-shaped member 164. The C-shaped member can be a solid material having no gaps or apertures therein. As shown in FIG. 5, an annular channel 165 is formed within the hollow cathode 160. During operation of the hollow cathode 160, the plasma generation zone 167 is formed within the annular channel 165 of the hollow cathode 160. For instance, the hollow cathode 160 can be electrically coupled to a generator 170, that when supplied with RF power, induces a plasma in the process gas in the plasma generation zone 167 of the plasma processing apparatus 100. For instance, as depicted in FIGS. 1-2, an RF generator 170 can be configured to provide electromagnetic energy through a matching network 172 to the hollow cathode 160. For instance, when supplied with RF power, the hollow cathode 160 provides energy to excite electrons from the process gas creating free electrons that facilitate plasma creation in the plasma generation zone 167.

Given the configuration of the hollow cathode 160, electrically charged plasma species (e.g., electrons and ions) can become trapped within the plasma generation zone 167 and can resonate within the zone 167 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm⁻³ to about 10¹⁵ cm⁻³, such as about 10¹³ cm⁻³. Within the hollow cathode 160, positive ions and high-energy electrons trapped between the walls of the hollow cathode 160 make many collisions with the process gas, thus ionizing the process gas and generating more electrons. Radicals created by collisions with the electrons and ions can escape, making the hollow cathode 160 an efficient producer of neutral radicals. Given the configuration of the hollow cathode 160 as described, high-density plasma can be generated due to the greatly enhanced probability of electron bombardment within the plasma generation zone 167 of the hollow cathode 160.

Further, as shown in FIG. 5, there is a distance D1 located between the first end 161 and the second end 162 of the hollow cathode 160. This distance D1 is generally in the vertical plane and can be modified in order to tune or affect the plasma in the hollow cathode 160. For instance, D1 can be larger or increased when lower pressure plasma processing is desirable. Further, D1 can be smaller or decreased when higher pressure plasma processing is desirable. In embodiments, D1 ranges from about 4 mm to about 15 mm, such as from about 5 mm to about 10 mm, such as from about 6 mm to about 9 mm. In certain embodiments, the distance D1 can be tuned depending on the specific process gas and/or process pressure. For instance, in embodiments where a nitrogen-containing gas is used and the pressure is about 0.7 Torr, the distance D1 can be between about 6 mm to about 10 mm, such as about 9 mm. In other embodiments, where the process gas contains a mixture of a fluorine-containing gas (e.g., CF₄), an oxygen-containing gas (e.g., O₂) and a carrier gas (e.g., Ar), and the pressure is about 0.3 Torr, the distance D1 can be between about 6 mm and to about 10 mm, such as about 9 mm.

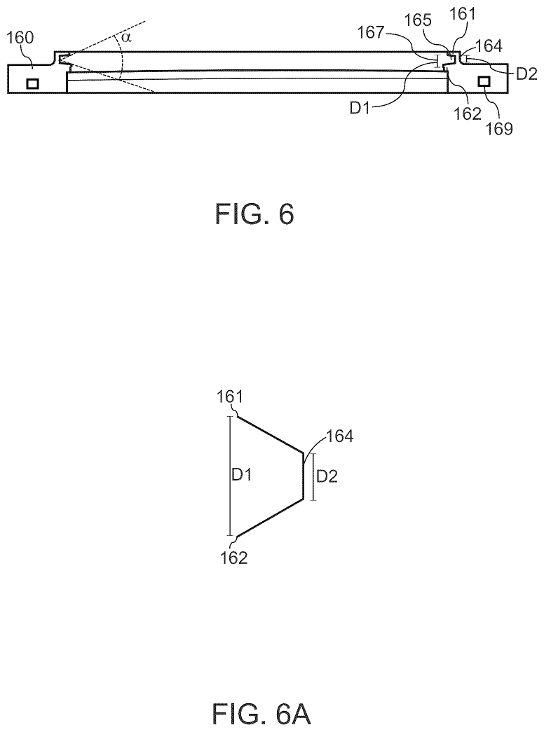

As shown in FIGS. 6 and 6A, a distance gradient can exist within the hollow cathode 160. The first end 161 and second end 162 can be disposed a greater distance D1 apart from each other as compared to the distance D₂ of the cathode along the C-shaped member 164. In such embodiments, the hollow cathode 160 forms a trapezoidal shaped hollow cathode. For instance, the first end 161 and second end 162 can be disposed such that an angle α is formed from the center of the C-shaped member 164 and extending out according to placement of the first end 161 and the second end 162. Thus, a larger opening is provided in the C-shaped cathode 160 about the first end 161 and the second end 162.

Other shaped hollow cathodes can be utilized according to the present disclosure without departing from the scope of the disclosure. For instance, stepped hollow cathodes having sidewalls extending out in a stepped portion can also be used. Additionally, different shapes and gradients can be used on the sidewall of the cathode in order to provide the desired shape for the hollow cathode.

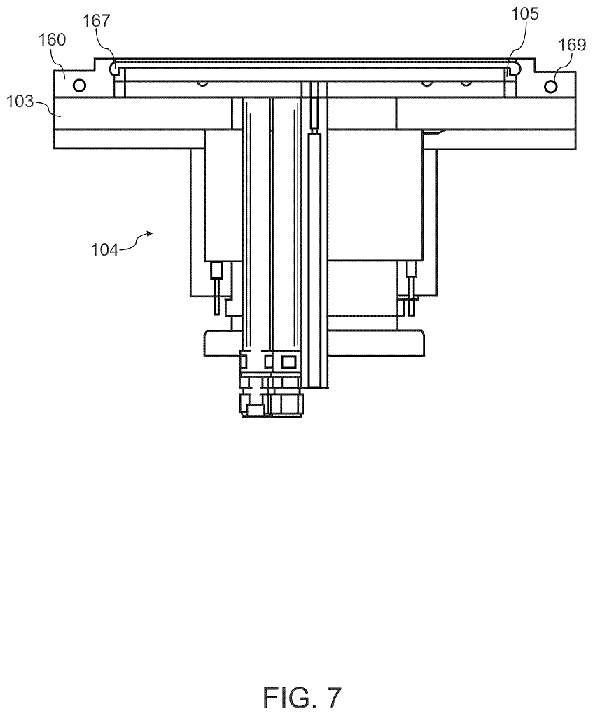

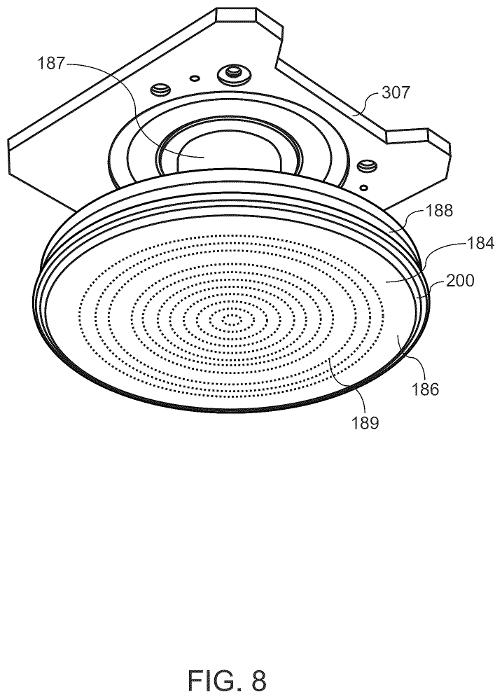

The hollow cathode 160 can be annular in nature (e.g., circular, ovular, etc.) As depicted in FIGS. 4-6, the hollow cathode 160 further includes an annular flange 166 extending outward from the bottom surface of the hollow cathode 160. Referencing FIG. 7, the annular flange 166 can be disposed on a portion of the workpiece support 104 to secure the hollow cathode 160 in the processing chamber 109. A barrier ring 105 is also disposed around a portion of the workpiece support 104. For instance, a barrier ring 105 can be disposed annular between an outer surface of the workpiece support 104 and the hollow cathode 160. The barrier ring 105 can be made from a material that can prevent plasma degradation of the workpiece support 104 during processing. The barrier ring 105 can be removed and replaced as needed through processing cycles. The barrier ring 105 and the hollow cathode 160 can be disposed on an insulating layer 103 that is disposed on a top surface of the workpiece support 104.

The hollow cathode 160 can be fluid cooled. As depicted in FIGS. 4-7, one or more conduits 169 can be disposed on the hollow cathode 160, for instance, the conduits 169 can be disposed internally in the hollow cathode 160. In other embodiments, it is contemplated that the conduits can be disposed on an external surface or surfaces of the hollow cathode 160 (not shown). Fluid can be flowed through the conduits 169 to cool the hollow cathode 160 either before, during, or after operation of the hollow cathode 160. Suitable fluids can include liquids or gases, including, but not limited to coolant fluids, water, and combinations thereof. Cooling of the hollow cathode 160 can facilitate operation of the hollow cathode 160 at higher powers to generate plasma at high density without the risk of overheating and with a reduced risk of sputtering of the cathode material.

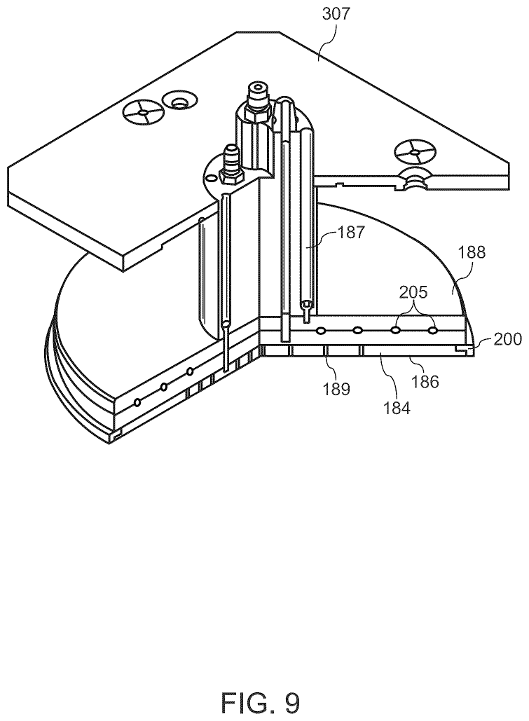

As depicted in FIGS. 8-9, a portion of a top insert 307 is illustrated. The top insert 307 can be inserted into the top 112 of the processing chamber and can form part of the inner surface 115 in the interior space 102 of the processing chamber 109. The top insert 307 can be coupled to a shield 188. As shown, the shield 188 can be disposed at the bottom of a conduit 187 that is coupled to the top insert 307. A barrier ring 200 is disposed around the perimeter of the shield 188. The showerhead 184 is disposed along the bottom surface of the shield 188 forming a workpiece facing surface 186. The workpiece facing surface 186 can include apertures 189 disposed thereon for delivery process gas to the interior space 102 of the processing chamber 109. The shield 188 can be cooled. For instance, as depicted in FIG. 9, the shield 188 can include one or more channels 205 disposed therein. Suitable cooling fluids (e.g., gases or liquids) can flow through the channels 205 to remove heat from the shield 188 due to processing. Suitable fluids include air, water, alcohol, or water and alcohol mixtures, however, any cooling fluid known can be used without departing from the scope of the disclosure.

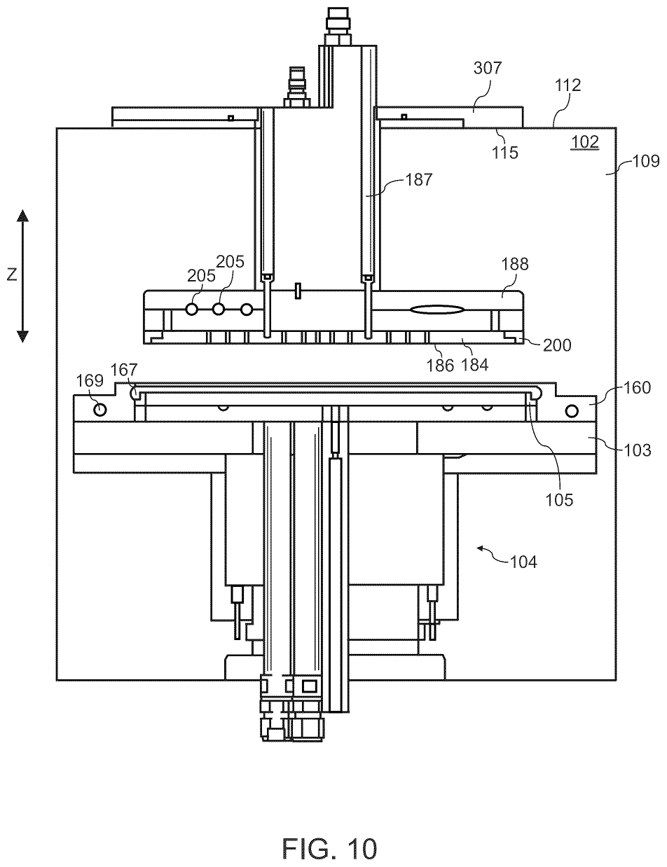

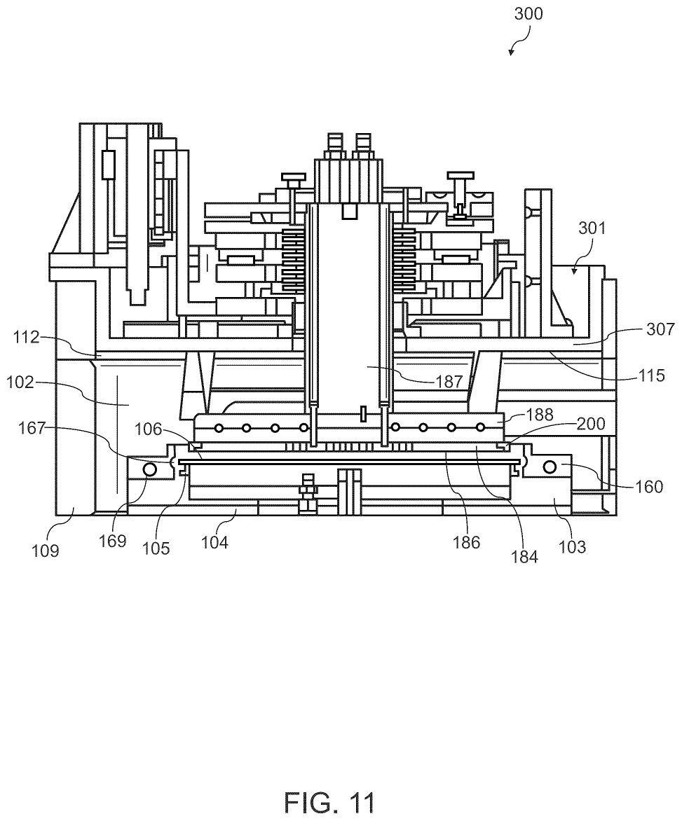

Referring to FIGS. 10-11, the shield 188 can be disposed within the processing chamber 109 at a location above the workpiece 106. For instance, the shield 188 can be disposed in an upper portion of the processing chamber 109. The shield 188 can be formed from any suitable material including metal, quartz, ceramic, or combinations thereof. In embodiments, the shield 188 is formed from a conductive material, such as a metal. In embodiments, the shield 188 can be grounded. For instance, suitable grounding components can be placed through the top 112 or the bottom 113 of the processing chamber 109 and electrically coupled to the shield 188 to ground the shield 188. In embodiments, the shield 188 is grounded to prevent charging of the shield 188 during workpiece processing.

As shown in FIG. 10, the shield 188 is disposed in processing chamber 109 in a non-processing position. For instance, the shield 188 is disposed vertically above the workpiece support 104. The shield 188 can be moved in the Z-direction to different locations within the processing chamber 109. For instance, as shown in FIG. 11, the shield 188 is disposed in a processing position in the processing chamber 109. Notably, in the processing position, the shield 188 is disposed closer to the top of the workpiece 106. To move the shield 188, one or more motors can be utilized to facilitate movement in the Z-direction in the processing chamber 109. When utilized in a processing position within the processing chamber 109, the shield 188 is configured to block one or more plasma species. For instance, as plasma species leave the plasma generation zone 167 they come into contact with the workpiece 106. The shield 188 can be configured to mechanically block one or more plasma species. For instance, the outer surface of the shield 188 can prevent plasma species from accessing the center of the workpiece 106 or other areas of the workpiece 106. Thus, utilization of the shield 188 can enhance exposure of the perimeter of the workpiece 106 to the plasma species. The barrier ring 200 is formed from materials to help protect the shield 188 from degradation due to plasma exposure. The barrier ring 200 can be removed and replaced from the outer perimeter of the shield 188 as needed due to processing demands. The barrier ring 200 can also help prevent plasma species from accessing undesired zones of the workpiece 106, such as the center or middle portion of the workpiece 106. Further, in embodiments, the size of the barrier ring 200 can be modified or changed according to desired process parameters. For instance, for processing larger workpieces, a larger barrier ring can be utilized.

Still referring to FIG. 11, during workpiece 106 processing, the shield 188 can be disposed a processing distance from the workpiece 106. The processing distance refers to the distance between the top surface of the workpiece 106 and the workpiece facing surface 186. For instance, the processing distance can be about 0.01 mm to about 5 mm, such as from about 0.05 mm to about 4.5 mm, such as from about 0.5 mm to about 4 mm, such as from about 1 mm to about 3 mm. Any suitable mechanism can be disposed within or external to the processing chamber 109 to facilitate vertical movement of the shield 188. For instance, lifts, bellows, and motors can be coupled to the shield 188 and can be configured to move the shield 188 within the plasma chamber 109. Process gas flows vertically down through the shield 188 and exits from a showerhead 184 between the top surface of the workpiece 106 and the workpiece facing surface 186. In such embodiments, gas flow velocity can be adjusted to adjust species formation in the plasma or can be adjusted to prevent species from accessing areas of the workpiece 106 located within the shield 188.

As depicted in FIG. 10, the shield 188 can be placed in a vertical position that is further away from the workpiece 106 and the workpiece support 104 (e.g., a non-processing position). Such a position is utilized to facilitate removal of the workpiece 106 from the apparatus 100. In such embodiments, the shield 188 can be at least 20 mm away from the workpiece 106 and/or the workpiece support 104. Further, in embodiments the top of the shield 188 can be flush with the first surface 115 of the top insert 307.

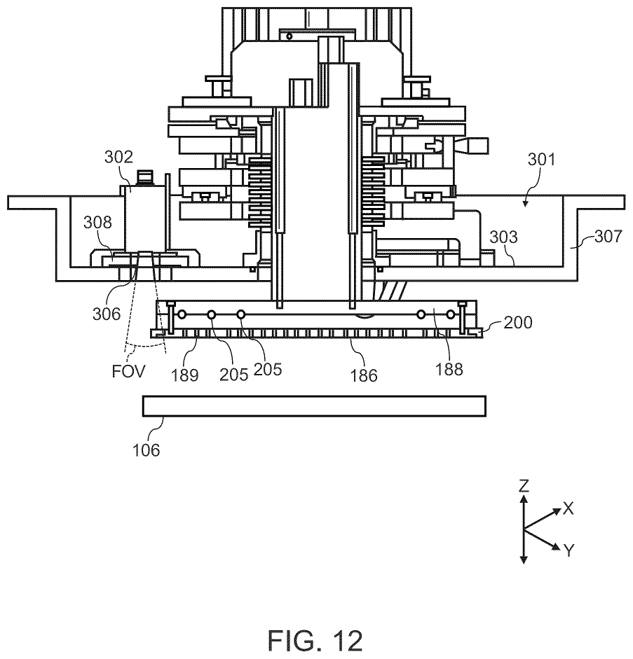

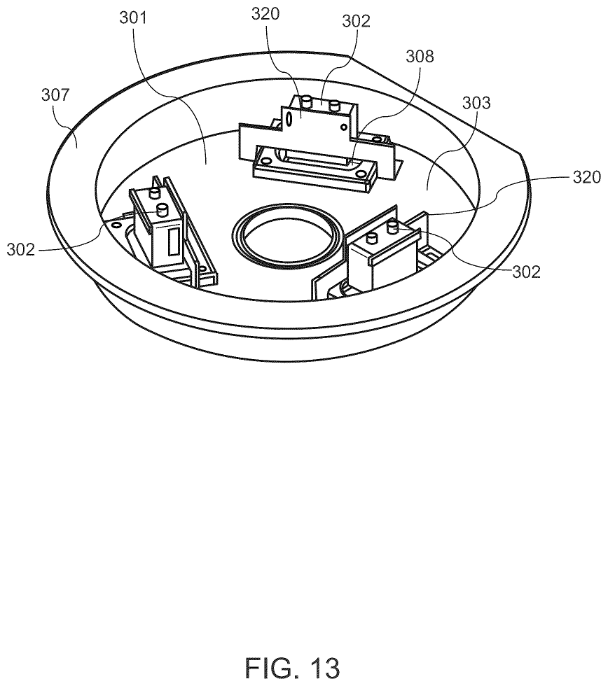

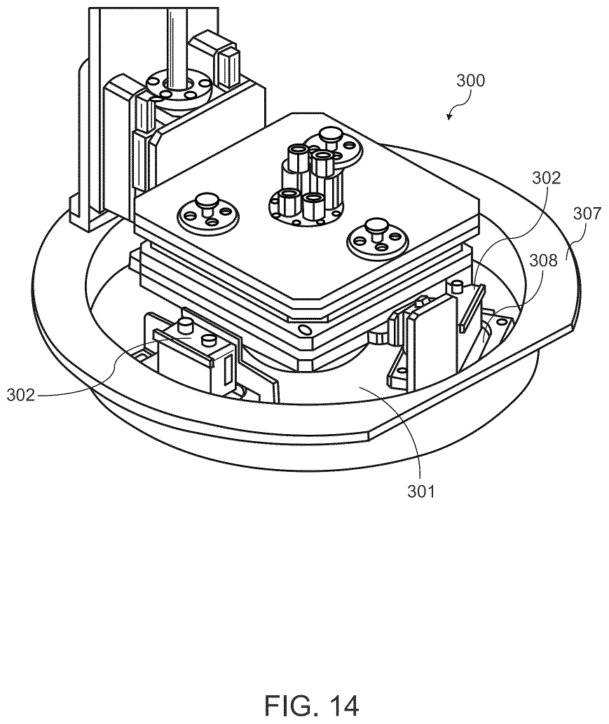

The processing apparatus 100 includes a centering system 300. The centering system 300 is configured to adjust the placement or position of the shield 188 in the interior space 102 of the processing chamber 109. For instance, the centering system 300 is configured to adjust the position of the shield 188 with respect to the Z-direction or an X-Y plane as shown in FIG. 12. For instance, as shown in FIGS. 12-13, the centering system can be coupled to an outer facing side of a top insert 307, that is the centering system 300 is not disposed inside the interior space 102 of the processing chamber 109. In such embodiments, the top insert 307 can include a concave portion 301 suitable for housing the components of the centering system 300. Components of the centering system 300 can include sensors, mechanical actuators, pins, ramps, etc. all configured to modify placement or position of the shield 188 in the processing chamber. For instance, as depicted in FIGS. 12-14, one or more sensors 302 can be placed in the concave portion 301 of the top insert 307. Specifically, the sensors 302 can be mounted on an inner surface 303 of the concave portion 301. One or more fasteners 320 (e.g., brackets) can be utilized to secure the sensor 302 to the inner surface 303. One or more apertures 306 are disposed through the top insert 307 such that the sensor 302 has a field of view (FOV) into the processing chamber 109. A sensor 302 is disposed over a window 308 to allow for view of the sensor 302 into the processing chamber 109. The window 308 can be comprised of any material but is preferable transparent to allow for proper view of the sensor 302 into the processing chamber 109. In embodiments, the window 308 can be formed from quartz or quartz-containing materials, sapphire, or combinations thereof.

In embodiments, the one or more sensors 302 can include laser sensors or cameras. In embodiments, the sensor 302 is capable of scanning or analyzing how much of the perimeter of the workpiece 106 extends beyond the outer perimeter of the shield 188, when the shield 188 is disposed in a processing position in the processing chamber 109. For instance, where a laser sensor is utilized, the laser can scan a portion of the perimeter of the shield 188 and the workpiece support 104 to determine locations where the shield 188 may or may not be centered with respect to the workpiece support 104. Such data generated by the sensor 302 can be transmitted to a controller 175. Once data is gathered, the controller 175 or other mechanical means can be used to modulate placement of the shield 188 to facilitate centering of the shield 188 for further workpiece 106 processing. For instance, if data provided by the sensor indicates that the shield 188 is not centered with respect to the workpiece support 104, the shield 188 can be adjusted either or both in the vertical Z direction and the X-Y plane to facilitate centering for workpiece processing. It is also contemplated, that the controller 175 can instruct components in the centering system 300 to move the shield 188 to facilitate centering of the shield 188 with respect to the workpiece support 104. For instance, the controller 175 can utilize data received from one or more of the sensors 302 to adjust the placement of the shield 188 in the processing chamber 109 in either the Z direction or the X-Y plane as indicated. Depending on the data received from the sensor 302, the controller can instruct bellows or motors to move the shield 188 up or down in a vertical manner in the Z-direction. In other embodiments, however, it should be appreciated that data from the sensor 302 can be utilized to manually adjust placement of the shield 188 in the Z-direction without facilitation from the controller 175. Should the sensors 302 indicate that placement of the shield 188 is off along the X-Y plane (e.g., the horizontal plane), then the controller 175 can instruct one or more motors within the centering system 300 to adjust placement of the shield 188. The shield 188 can be centered prior to placement of a workpiece 106 in the processing chamber 109. Further, once placement adjustments of the shield 188 have been made, the Z-direction and/or X-Y position of the shield 188 can be locked so that placement of the shield 188 is not modified during subsequent workpiece 106 processing. It is also contemplated, that once data is received from the sensors 302 adjustments to the shield 188 can be completed manually. For instance, in embodiments, it should be appreciated that data from the sensor 302 can be utilized to manually adjust placement of the shield 188 in the Z-direction or X-Y direction without utilization of the controller or other automated components.

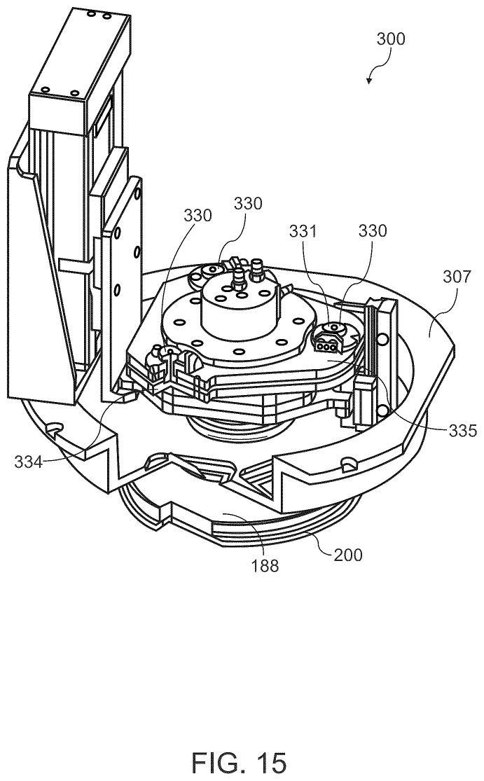

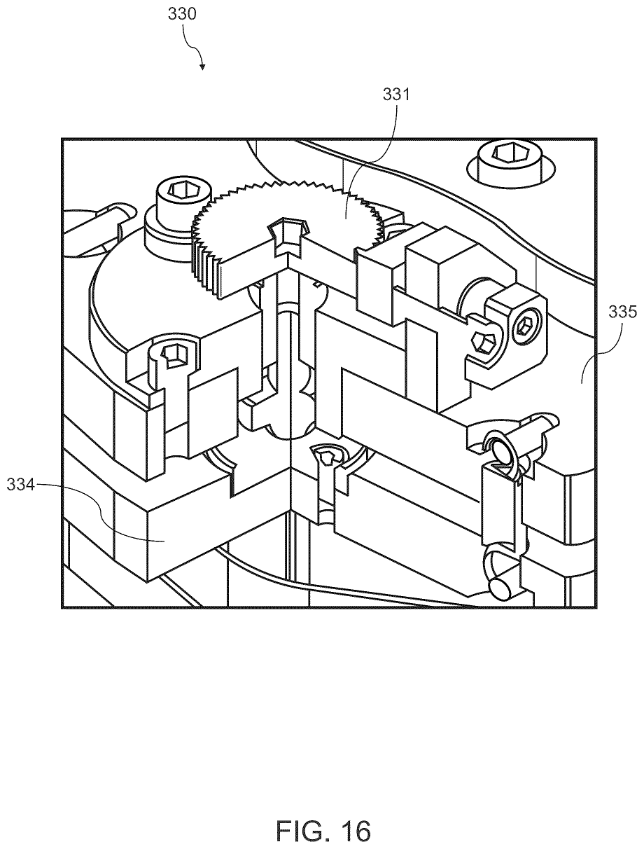

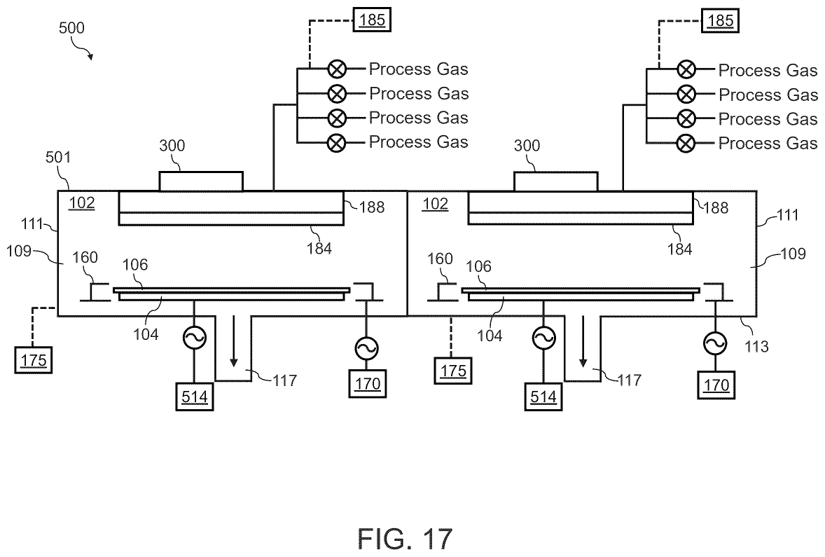

In embodiments, the centering system 300 is configured to modify an angle of the workpiece facing surface of the shield 188 (e.g., tilting the shield 188) respective to a top surface of the workpiece 106. For instance, during processing, non-uniformity can develop on workpieces based on spacing differences between the workpiece facing surface 186 and the top surface of the workpiece 106. In such embodiments, the centering system 300 can be utilized to modify placement of the shield 188 to facilitate uniform processing. In such embodiments, angular adjustments can be made to the shield 188. For instance, as shown in FIGS. 15-16, an angular adjustment device 330 can be utilized to modify placement of the shield 188 in the processing chamber 109. The angular adjustment device 330 includes a dial 331 coupled to one or more plates 335 and is configured to move a portion of the shield 188 towards or away from the workpiece support 104 via turning the dial 331. For instance, articulation of the dial 331 modifies placement of a plate 334 disposed outside of the processing chamber 109, which can influence angular placement of the shield 188 within the processing chamber 109. For instance, as the dial 331 is articulated the plate 334 can be tilted which can tilt the shield in the processing chamber 109.

As shown in FIG. 15, the centering system 300 can include one or more, such as a plurality of angular adjustment devices 330 disposed thereon. For instance, in an embodiment three angular adjustment devices are disposed in equidistance around the perimeter of a plate 335 that generally corresponds to placement equidistance with respect to the shield 188. Thus, to move only a certain portion of the shield, one angular adjustment device 330 can be utilized. Accordingly, if workpiece processing non-uniformity is observed in a certain area on a workpiece 106, the corresponding angular adjustment device 330 can be modified to bring the shield 188 closer or farther away from the workpiece 106 for the area in which the non-uniformity is observed.

In embodiments, the angular adjustment devices 300 can be manually adjusted or can be adjusted using the controller 175 provided herein. For instance, uniformity processing data can be supplied to the controller 175 which can then utilize one or more devices (e.g., pneumatic devices, motors, etc.) to turn the dial 331 so that angular placement of the shield 188 can be accomplished. Further, angular adjustment of the shield 188 can be modified and controlled while there is no workpiece 106 present in the processing chamber. Further, once angular adjustments of the shield 188 have been made, the angular position of the shield 188 can be locked so that the angular placement of the shield 188 is not modified during subsequent workpiece 106 processing.

A controller 175 can be coupled to various components of the plasma processing apparatus 100 to operate the components in a desired manner, see FIG. 1. For example, the shield 188 can be moved to different vertical positions within the processing chamber 109 via the controller 175. For instance, a processing position and non-processing position can be determined and provided to the controller 175. The controller 175 can include one or more processors and one or more memory devices. The memory device can store and implement computer readable instructions that when executed by the one or more processors cause the one or more processors to perform operations, including implementing any of the control functionality of the present disclosure. Accordingly, when the desired shield 188 position is provided to the controller 175, the controller 175 can operate the mechanical elements in order to move the shield 188 to the desired location within the processing chamber 109. Further, the controller 175 can be configured to operate one or more components within the centering system 300 to facilitate proper placement of the shield 188 in the processing chamber 109. For instance, should sensor 302 data indicate that the shield 188 is not properly centered with respect to the workpiece support 104, the controller 175 can instruct motors, bellows, pins, or other mechanical actuators in the centering system 300 to adjust the location of the shield 188 in the processing chamber 109. Further, a desired vacuum pressure for the processing chamber 109 can be determined and provided to the controller 175. The controller 175 can then operate the vacuum pump or other exhausts to maintain the desired vacuum pressure for the processing chamber 109.

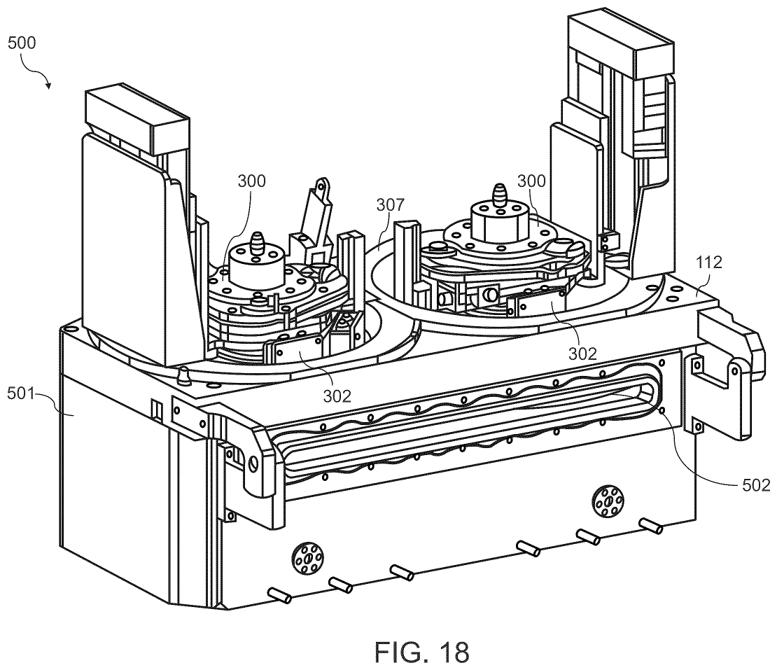

FIG. 17 depicts an example plasma processing apparatus 500 having at least two processing chambers 109 disposed in a processing module 501. In such an embodiment, each processing chamber 109 includes the components as depicted in FIG. 1. Namely, the processing chambers 109 include a workpiece support 104, hollow cathode 160, and a shield 188 disposed within the interior space 102 of the processing chamber 109. Such a processing apparatus 500 allows for processing of multiple (e.g., at least two) workpieces 106 simultaneously, which can significantly increase processing capabilities and reduce the amount of processing time needed to process large quantities of workpieces. FIG. 18 depicts a portion of the plasma processing apparatus 500, namely, partial perspective view of a processing module 501 including at least two processing chamber 109. As shown in FIG. 18, the top 112 of the processing apparatus 500 can include one or more top inserts 307 disposed therein. As noted, a portion of the top insert 307 can form the inner surface 115 of the top 112 in the processing chamber 109. As depicted, the top inserts 307 can include components of the centering system 300, such as the sensors 302. Further, additional motors, bellows, mechanical actuators, etc. can be disposed on or within the top inserts 307 in order to facilitate adjustment of placement of the shield 188 in the processing chamber 109. One or more slots 502 are disposed in the sidewalls of the processing chamber 109 in order to facilitate entry and exit of workpieces from the processing chambers 109. For instance, one or more robot arms carrying one or more workpieces can be utilized to place workpieces on the workpiece support 104 disposed in each of the processing chambers 109 of apparatus 500. A workpiece treatment method (e.g., etch) can be performed simultaneously on each workpiece. Once completed, the robot arms can be extended into the processing chambers 109 to remove the workpieces therein. While a single slot 502 is depicted, the disclosure is not so limited and additional slots 502, such as at least two slots can be utilized without departing from the scope of the present disclosure.

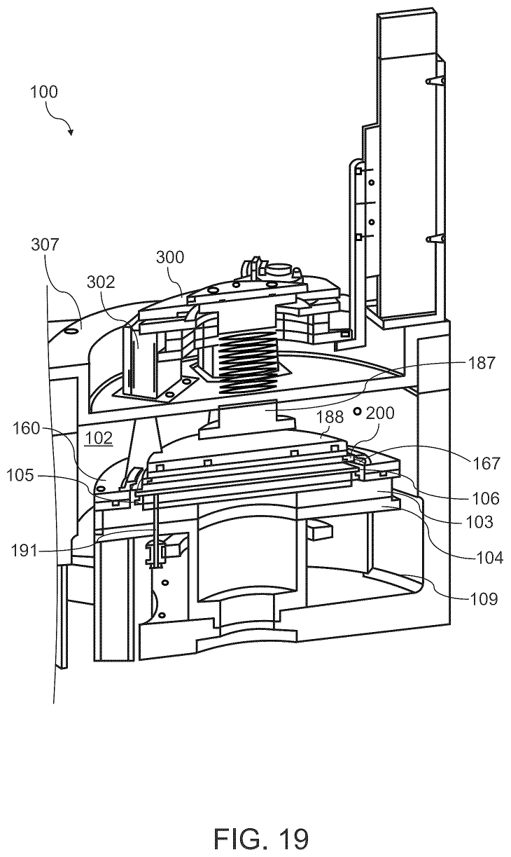

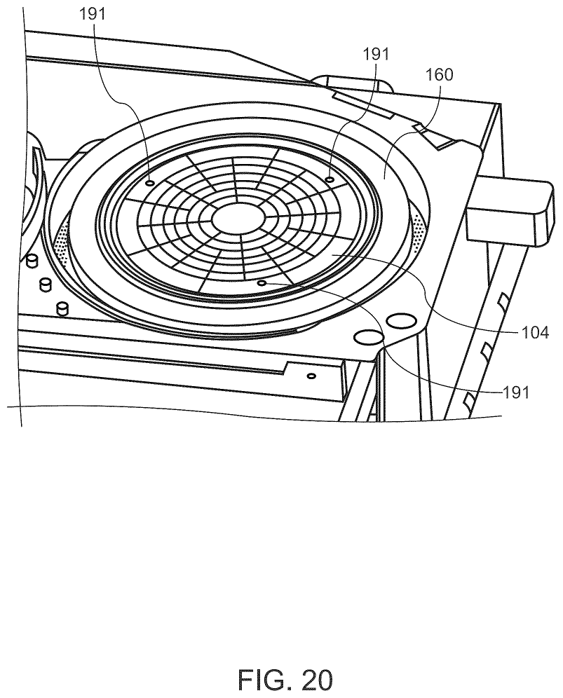

FIGS. 19-20 depicts a plasma processing apparatus 100 having one or more pins 191 configured to raise the workpiece 106 from the top surface of the workpiece support 104. For instance, the workpiece support 104 can have one or more pins 191, such as a plurality of pins 191, configured to raise up from the top surface of the workpiece support 104 to lift the workpiece off the surface of the workpiece support 104. Once lifted, one or more robot arms can be disposed under the workpiece 106 and can remove the workpiece 106 from the processing chamber 109. Further, in the lifted position, a workpiece 106 can also be placed on the pins 191 and then lowered into a processing position on the workpiece support 104. For instance, as depicted in FIG. 20, the pins 191 are disposed within the workpiece support 104, such that no portion of the pin 191 extends above the top surface of the workpiece support. Any suitable mechanism can be utilized to lift and lower the pins 191 as would be known. Such mechanisms can include actuators (e.g., mechanical or electromechanical actuators), motors, etc.

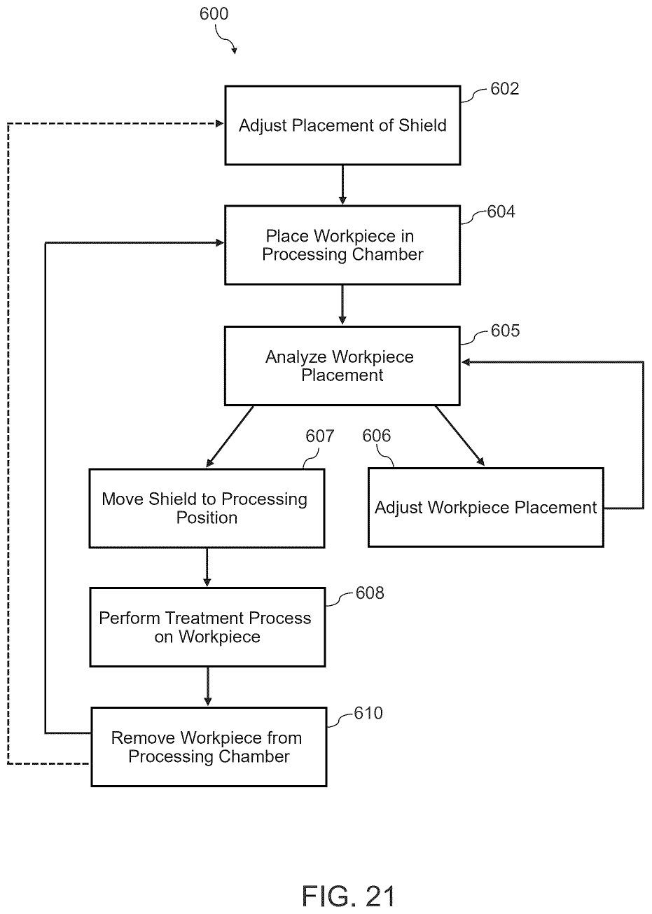

FIG. 21 depicts a flow diagram of one example method (600) according to example aspects of the present disclosure. The method (600) will be discussed with reference to the plasma processing apparatus 100 of FIGS. 1-13 by way of example. The method (600) can be implemented in any suitable plasma processing apparatus. FIG. 21 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (602), the method can include centering the shield 188 or adjusting the placement of the shield 188 with respect to the workpiece support 104. For instance, sensors 302 disposed in a top insert 307 of the top 112 can be utilized to obtain data regarding placement of the shield 188 with respect to a center axis aligned with the center of the workpiece support 104. Further sensors 302 can be utilized to determine if the shield is properly centered with respect to the workpiece support. Sensor data can be provided to the controller 175, which can then operate one or more components of the centering system 300 to modify placement of the shield 188 in the interior space 102 of the processing chamber 109. For instance, the shield 188 can be moved in a vertical direction (Z-direction) or in the X-Y plane. Further angular adjustments can also be performed by the centering system 300. In embodiments, once placement adjustments of the shield 188 are performed, the shield placement with respect to angular adjustments or the X-Y plane can be locked, such that any adjustments are not modified during workpiece 106 processing.

At (604), the method can include placing a workpiece 106 in the processing chamber 109 of a plasma processing apparatus 100. For instance, the workpiece 106 can be placed on a workpiece support 104 disposed in the processing chamber 109.

At (605), the method can include analyzing the workpiece 106 placement on the workpiece support 104. For instance, sensors 302 disposed in a top insert 307 of the top 112 can be utilized to obtain data regarding placement of the workpiece 104 with respect to the shield 188 and the workpiece support 104. In such a manner, the sensors 302 can be utilized to determine if the workpiece is properly centered with respect to the workpiece support 104.

At (606), the method can include adjusting placement of the workpiece 106 on the workpiece support 104. For instance, if sensor data indicates misplacement of the workpiece 106 one or more robot arms can enter the interior space 102 of the processing chamber 109 to physically modify the placement of the workpiece 106 on the workpiece support 104. As indicated, (605) and (606) can be repeated or alternated until proper placement of the workpiece 106 on the workpiece support 104 is achieved.

At (607), the method can include moving the shield 188 to a processing location within the processing chamber 109. For instance, one proper placement of the workpiece 106 on the workpiece support 104 is achieved, the shield 188 can be moved to a vertical position that is a desired processing distance from the workpiece 106. For instance, the processing distance between the shield 188 and the workpiece 106 can be from about 0.01 mm to about 1 mm, from about 0.1 mm to about 0.8 mm, such as about 0.3 mm. Any suitable mechanism can be disposed within or external to the processing chamber 109 to facilitate vertical movement of the shield 188. For instance, lifts, bellows, and motors can be coupled to the shield 188 and can be configured to move the shield 188 within the plasma chamber 109. One or more controllers 175 can be configured to operate mechanical elements configured to move the shield 188 vertically within the processing chamber 109.

At (608), the method can include performing a treatment process on the workpiece 106. For example, the treatment process can include a plasma treatment process. In certain embodiments, the treatment process includes a plasma etch treatment process. The plasma etch treatment process can selectively remove one or more material layers from the workpiece 106. Specifically, in embodiments, the plasma treatment process is a plasma etch process configured to remove material layers from a peripheral portion of the workpiece 106. In other embodiments, the treatment process includes a plasma deposition process. For instance, the plasma deposition process can selectively deposit one or more material layer on the workpiece 106. In embodiments, the plasma treatment process is a plasma deposition process configured to deposit material layer on a peripheral portion of the workpiece 106. Other plasma processes can be used to modify the material layers present on the workpiece. For example, plasma-based surface treatment processes can be utilized to modify the surface morphology of the workpiece or to modify the chemical composition of layers on the workpiece. Any other, known suitable plasma-based processing for workpieces can be performed on the workpiece 106.

In embodiments, the treatment process includes using a hollow cathode 160 to generate a plasma within the processing chamber 109. For instance, the hollow cathode 160 is disposed adjacent to a perimeter of the workpiece support 104 and the workpiece 106. The distance between the perimeter edge of the workpiece 106 and the hollow cathode 160 may be in a range from about 1 mm to about 10 mm, such as from about 2 mm to about 9 mm, such as from about 3 mm to about 8 mm, such as from about 4 mm to about 7 mm, such as from about 5 mm to about 6 mm. In certain embodiments, the distance between the perimeter edge of the workpiece 106 and the hollow cathode 160 is from about 1 mm to about 5 mm. For instance, in certain embodiments, the distance between the perimeter edge of the workpiece 106 and the hollow cathode 160 is more than 5 mm so as not to negatively affect the stability of the plasma generated in the hollow cathode 160. The hollow cathode can be formed from metal materials, such as aluminum.

In embodiments, as shown in FIG. 5, the hollow cathode 160 is a C-shaped hollow cathode. The hollow cathode 160 can have a first end 161 and a second end 162 connected via a C-shaped member 164. The C-shaped member 164 can be a solid material having no gaps or apertures therein. As shown, an annular channel 165 is formed within the hollow cathode 160. During operation of the hollow cathode 160, the plasma generation zone 167 is formed within the annular channel 165 of the hollow cathode 160. For instance, the hollow cathode 160 can be electrically coupled to a generator 170, that when supplied with RF power, induces a plasma in the process gas in the plasma generation zone 167 of the plasma processing apparatus 100. For instance, an RF generator 170 can be configured to provide electromagnetic energy through a matching network 172 to the hollow cathode 160.

Given the configuration of the hollow cathode 160, plasma species (e.g., electrons, ions, and radicals) can become trapped within the plasma generation zone 167 and can resonate within the zone 167 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm⁻³ to about 10¹⁵ cm⁻³, such as about 10¹³ cm⁻³. Within the hollow cathode 160, positive ions and high-energy electrons trapped between the walls of the hollow cathode 160 make many collisions with the process gas, thus ionizing the process gas and generating more electrons. Radicals created by collision with the electrons and ions can escape, making the hollow cathode 160 an efficient producer of neutral radicals. Given the configuration of the hollow cathode 160 as described, high-density plasma can be generated due to the greatly enhanced probability of electron bombardment within the plasma generation zone 167 of the hollow cathode 160. Thus, during the plasma treatment process, the hollow cathode 160 can be utilized to expose the perimeter of the workpiece 106 to plasma species.

Further, during the plasma treatment process, a shield 188 can be utilized to further direct plasma species to the perimeter of the workpiece 106. For instance, the shield 188 is configured to mechanically block one or more plasma species. For instance, the outer perimeter of the shield 188 and the barrier ring 200 can prevent plasma species from accessing the center or other areas of the workpiece 106. Thus, utilization of the shield 188 can enhance exposure of the perimeter of the workpiece 106 to the plasma species. Accordingly, the plasma treatment process can include utilizing a shield 188 to prevent one or more plasma species from contacting a center portion of the workpiece 106. Further, process gas flow through the showerhead 184 disposed on the shield 188 can be utilized to block plasma species from accessing the center of the workpiece 106. For instance, as process gas flows through the showerhead 184 disposed on the bottom surface of the shield 188 and exits between the workpiece facing surface 186 and the top of the workpiece 106, increasing the velocity of the process gas flow can further prevent plasma species from accessing the center of the workpiece 106.

The workpiece support 104 can include a bias source having a bias electrode 510 in the workpiece support 104. The bias electrode 510 can be coupled to an RF power generator 514 via a suitable matching network 512. When RF power is applied to the bias electrode 510, species generated in the plasma are attracted to the perimeter of the workpiece 106 and away from the plasma generation zone 167 in the hollow cathode 160. For instance, when voltage is applied to the bias electrode, ions from the plasma in the plasma generation zone 167 are attracted to the perimeter of the workpiece 106. Thus, ion acceleration can be achieved via the bias source in the workpiece support 104. Accordingly, the plasma treatment process can include accelerating one or more species from the plasma towards a perimeter of the workpiece utilizing a bias source disposed in the workpiece support 104.

At (610) the method can include removing the workpiece from the processing chamber 109. For instance, the workpiece 106 can be removed from workpiece support 104 in the processing chamber 109. To facilitate removal of the workpiece 106, the shield 188 can be raised to a non-processing position in the processing chamber 109. One or more pins 191 can then be utilized to lift the workpiece 106 from the workpiece support 104, such that it can be removed from the processing chamber by a robot arm. The plasma processing apparatus can then be conditioned for future processing of additional workpieces.

As noted, after (610), the method can continue with either (602) or (604). For instance, in certain embodiments, another workpiece can be placed in the processing chamber as described in (604) and can be processed. However, after (610), if additional adjustments are necessary for the shield 188, such adjustments can then be made prior to placing another workpiece 106 in the processing chamber 109 for processing.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a processing chamber;
a workpiece support disposed in the processing chamber configured to support a workpiece during processing;
a hollow cathode disposed in the processing chamber configured to produce a plasma in the processing chamber, wherein the hollow cathode is disposed adjacent to a perimeter of the workpiece support and the workpiece;
a gas distribution system configured to provide process gas to the processing chamber; and
a shield disposed in the processing chamber, the shield is configured to be adjusted with respect to an X-Y plane.

2. The plasma processing apparatus of claim 1, wherein the shield is configured to move in a Z-direction to a processing position.

3. The plasma processing apparatus of claim 1, wherein the shield includes a first barrier ring disposed around the perimeter of the shield.

4. The plasma processing apparatus of claim 1, wherein the shield further comprises a gas showerhead.

5. The plasma processing apparatus of claim 1, comprising a second barrier ring disposed on an outer surface of the workpiece support.

6. The plasma processing apparatus of claim 1, comprising a centering system configured to modify a location of the shield in the processing chamber.

7. The plasma processing apparatus of claim 6, wherein the centering system is configured to provide data to allow for modification of the placement of the shield with respect to an X-Y plane.

8. The plasma processing apparatus of claim 7, wherein the centering system comprises one or more motors configured to move the shield in the X-Y plane.

9. The plasma processing apparatus of claim 6, wherein the centering system is configured to modify an angle of a workpiece facing surface of the shield.

10. The plasma processing apparatus of claim 6, wherein the centering system comprises one or more sensors disposed on a top of the processing chamber, the one or more sensors configured to generate data regarding placement of the shield and to transmit the data to a controller.

11. The plasma processing apparatus of claim 10, wherein the one or more sensors comprise one or more laser sensors.

12. The plasma processing apparatus of claim 1, wherein the plasma is configured to etch a peripheral portion of the workpiece.

13. The plasma processing apparatus of claim 1, wherein the hollow cathode comprises a plasma generation zone disposed within a portion of the hollow cathode between the workpiece and the hollow cathode.

14. The plasma processing apparatus of claim 1, wherein the hollow cathode is a C-shaped hollow cathode.

15. The plasma processing apparatus of claim 1, wherein the hollow cathode is a trapezoidal-shaped hollow cathode.

16. The plasma processing apparatus of claim 1, wherein the hollow cathode is fluid cooled.

17. The plasma processing apparatus of claim 1, wherein a distance between a perimeter edge of the workpiece and the cathode is in a range of about 1 mm to about 10 mm.

18. A processing system for processing a plurality of workpieces, comprising:
a processing module comprising a first processing chamber and a second processing chamber;
a first workpiece support disposed in the first processing chamber configured to support a first workpiece during processing;
a second workpiece support disposed in the second processing chamber configured to support a second workpiece during processing;
a first hollow cathode disposed in the first processing chamber configured to produce a plasma in the first processing chamber, wherein the first hollow cathode is disposed adjacent to a perimeter of the first workpiece support and a first workpiece;
a second hollow cathode disposed in the second processing chamber configured to produce a second plasma in the second processing chamber, wherein the second hollow cathode is disposed adjacent to a perimeter of the second workpiece support and the second workpiece;
a first top including a first shield having a first workpiece facing surface, the first shield configured to be adjusted with respect to an X-Y plane;
a second top including a second shield having a second workpiece facing surface, the second shield configured to be adjusted with respect to an X-Y plane; and
a gas distribution system configured to provide process gas to the first processing chamber and the second processing chamber.

19. The processing system of claim 18, comprising a first centering system configured to modify a first location of the first shield in the first processing chamber and a second centering system configured to modify a second location of the second shield in the second processing chamber.

20. A method for processing a workpiece in a plasma processing apparatus, the method comprising:
centering a shield disposed in a processing chamber;
transferring a workpiece to a workpiece support disposed in a processing chamber;
moving the shield to a processing position in the processing chamber;
performing a treatment process on a peripheral portion of the workpiece with plasma generated from a hollow cathode disposed in the processing chamber, the hollow cathode disposed adjacent to a perimeter of the workpiece support; and
optionally, removing the workpiece from the processing chamber.
